(19) United States
(12) Patent Application Publication
(10) Pub. No.: US 2025/0176397 A1
(43) Pub. Date: May 29, 2025

(54) DISPLAY DEVICE

(71) Applicant: Samsung Display Co., LTD., Yongin-si (KR)

(72) Inventors: Sun-Kyu JOO, Yongin-si (KR); Seon Uk LEE, Yongin-si (KR); Cheol SHIN, Yongin-si (KR); Keun Chan OH, Yongin-si (KR); Woo-Man JI, Yongin-si (KR); You Young JIN, Yongin-si (KR); Tae Hyung HWANG, Yongin-si (KR)

(73) Assignee: Samsung Display Co., LTD., Yongin-si (KR)

(21) Appl. No.: 18/808,872

(22) Filed: Aug. 19, 2024

(30) Foreign Application Priority Data
Nov. 28, 2023 (KR) 10-2023-0167882

(51) Int. Cl. H10K 59/38; H10K 59/122

(52) U.S. Cl. CPC H10K 59/38; H10K 59/122

(57) ABSTRACT

A display device that includes a first substrate, a transistor disposed on the first substrate, a light emitting element electrically connected to the transistor, an encapsulation layer disposed on the light emitting element, a bank disposed on the encapsulation layer and including a first opening, a second opening, and a third opening, a first color conversion layer disposed in the first opening, a transmission layer disposed in the third opening, and a filling layer disposed on the first color conversion layer and the bank, wherein a height of the transmission layer may be greater than a height of the bank, and a surface of the filling layer and a surface of the transmission layer may be disposed on a same plane.

### CROSS-REFERENCE TO RELATED APPLICATIONS

This application claims priority under 35 U.S.C. 119 from Korean Patent Application No. 10-2023-0167882 filed on Nov. 28, 2023 in the Korean Intellectual Property Office, the entire contents of which are incorporated herein by reference.

### BACKGROUND

### 1. Technical Field

This disclosure relates to a display device.

### 2. Description of the Related Art

The light emitting element is a device that emits light in case that an exciton is formed and stabilized in a light emitting layer formed between an anode and a cathode, through the combination of a hole supplied from the anode and an electron supplied from the cathode.

Light emitting elements have various advantages such as wide viewing angle, fast response speed, thinness, and low power consumption, so they are widely applied to various electrical and electronic devices such as televisions, monitors, and mobile phones.

Recently, a display device including a color conversion layer has been proposed to implement a highly efficient display device.

The color conversion layer may convert incident light into a different color.

### SUMMARY

The embodiments are intended to provide a high-resolution display device by providing a transparent transmission layer that may function as a column spacer, thereby eliminating the need for an area to form a column spacer.

A display device according to an embodiment may include a first substrate, a transistor disposed on the first substrate, a light emitting element electrically connected to the transistor, an encapsulation layer disposed on the light emitting element, a bank disposed on the encapsulation layer and including a first opening, a second opening, and a third opening, a first color conversion layer disposed in the first opening, a transmission layer disposed in the third opening, and a filling layer disposed on the first color conversion layer and the bank, wherein a height of the transmission layer may be greater than a height of the bank, and a surface of the filling layer and a surface of the transmission layer may be disposed on a same plane.

The display device may further include a second color conversion layer disposed in the second opening.

The height of the bank may be larger than each of a height of the first color conversion layer and a height of the second color conversion layer.

The display device may further include a second substrate overlapping the first substrate, and a color filter disposed on a surface of the second substrate.

The filling layer may be disposed between the color filter and the first color conversion layer.

At least a portion of the transmission layer may be disposed on an upper surface of the bank.

A first thickness of the transmission layer may be equal to a second thickness of the filling layer disposed on a surface of the bank.

The first substrate may include a non-display area, the display device may further comprise a first color filter, a second color filter, and a third color filter, and at least two of the first color filter, the second color filter, and the third color filter may overlap each other in the non-display area.

The bank and the filling layer may be disposed in the non-display area.

A display device according to an embodiment may include a first substrate, a transistor disposed on the first substrate, a light emitting element electrically connected to the transistor, an encapsulation layer disposed on the light emitting element, and a second substrate overlapping the first substrate, a bank disposed between the first substrate and the second substrate and including an opening, and a color conversion layer and a transmission layer respectively disposed in the opening, and a height of the transmission layer may be greater than a height of the bank.

The opening in the bank may include a first opening, a second opening, and a third opening, and the color conversion layer may include a first color conversion layer disposed in the first opening, a second color conversion layer disposed in the second opening, and the transmission layer may be disposed in the third opening.

The height of the bank may be larger than each of a height of the first color conversion layer and a height of the second color conversion layer.

The display device may further include a color filter disposed between the second substrate and the color conversion layer.

The display device may further include a filling layer disposed between the color conversion layer and the encapsulation layer.

A surface of the filling layer and a surface side of the transmission layer may be disposed on a same surface.

A first thickness of the transmission layer may be equal to a second thickness of the filling layer disposed on a surface of the bank.

The transmission layer may be in contact with the encapsulation layer.

The first substrate may include a non-display area, the display device may further comprise a first color filter, a second color filter, and a third color filter, at least two of the first color filter, the second color filter and the third color filter may overlap each other in the non-display area.

The bank and the filling layer may be disposed in the non-display area.

At least a portion of the transmission layer may be disposed on a surface of the bank.

According to embodiments, by providing a transparent transmission layer capable of functioning as a column spacer, an area for forming a column spacer may not be required, and thus a high-resolution display device may be provided.

### BRIEF DESCRIPTION OF THE DRAWINGS

FIG. 1 is a schematic exploded perspective view of a display device according to an embodiment;

FIG. 2 is a schematic cross-sectional view of a display panel according to an embodiment; and

FIG. 3 and FIG. 4 are schematic cross-sectional views of a display panel according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

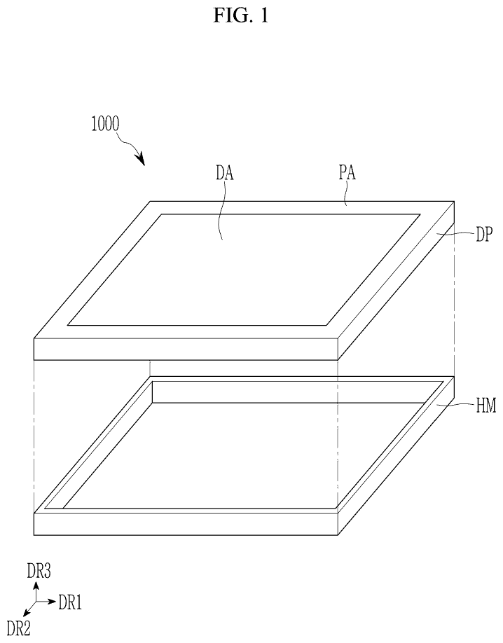

Hereinafter, a display device according to an embodiment will be described with reference to FIG. 1.

FIG. 1 is a schematic exploded perspective view of a display device according to an embodiment.

Referring to FIG. 1, a display device 1000 according to an embodiment may include a display panel DP and a housing HM.

One side of the display panel DP on which the image may be displayed may be parallel to the side defined by the first direction DR1 and the second direction DR2.

The third direction DR3 indicates the normal direction of one side on which the image may be displayed, that is, the thickness direction of the display panel DP.

The front (or upper) and back (or lower) surfaces of each member may be separated in the third direction DR3.

However, the directions indicated by the first to third directions DR1, DR2, and DR3 may be relative concepts and may be converted to other directions.

The display panel DP may be an approximately flat rigid display panel, but is not limited thereto and may be a flexible display panel.

The display panel DP may be made of an organic light emitting display panel.

However, the type of display panel DP is not limited to this and may be made of various types of panels.

For example, the display panel DP may be a liquid crystal display panel, an electrophoretic display panel, an electrowetting display panel, etc.

The display panel DP may be a next-generation display panel such as a micro light emitting diode display panel, a quantum dot light emitting diode display panel, or a quantum dot organic light emitting diode display panel.

Micro LED display panels may be made up of light emitting diodes measuring in a range of about 10 to about 100 micrometers to form each pixel.

These micro light emitting diode display panels have the following advantages: they use inorganic materials, the backlight may be omitted, the response speed may be fast, high brightness may be achieved with low power, and it does not break in case that bent.

Quantum dot light emitting diode display panels may be made by attaching a film containing quantum dots or forming them with a material containing quantum dots.

Quantum dots may be particles made of inorganic materials such as indium and cadmium, emit light on their own, and have a diameter of several nanometers or less.

By controlling the particle size of quantum dots, light of a desired color may be displayed.

The quantum dot organic light emitting diode display panel uses a blue organic light emitting diode as a light source and displays color by attaching a film containing red and green quantum dots on it or depositing a material containing red and green quantum dots.

The display panel DP according to an embodiment may be various other display panels.

As shown in FIG. 1, the display panel DP includes a display area DA where an image may be displayed, and a non-display area PA adjacent to the display area DA.

The non-display area PA may be an area where images may not be displayed.

For example, the display area DA may have a square shape, and the non-display area PA may have a shape surrounding the display area DA.

However, the shape of the display area DA and the non-display area PA may be relatively designed without being limited thereto.

The housing HM provides an internal space.

The display panel DP may be mounted inside the housing HM.

In addition to the display panel DP, various electronic components, such as a power supply part, a storage device, and an audio input/output module, may be mounted inside the housing HM.

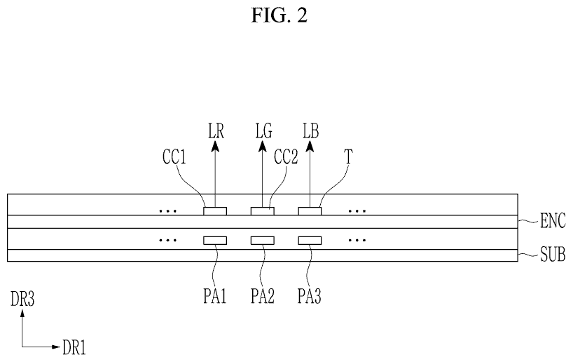

Hereinafter, the display area of the display panel according to an embodiment will be described with reference to FIG. 2.

FIG. 2 is a schematic cross-sectional view of a display panel according to an embodiment.

Referring to FIG. 2, multiple pixels PA1, PA2, and PA3 may be formed on the substrate SUB corresponding to the display area DA of FIG. 1.

Each pixel (PA1, PA2, and PA3) may include multiple transistors and a light emitting element electrically connected to the transistors.

This specification describes an embodiment in which multiple pixels (PA1, PA2, and PA3) may be repeatedly arranged in a stripe shape, but is not limited thereto, and the shape and arrangement of each pixel may be modified in various ways.

An encapsulation layer ENC may be disposed on the pixels (PA1, PA2, and PA3).

The display area DA may be protected from external air or moisture through the encapsulation layer ENC.

The encapsulation layer ENC may be integrally provided to overlap the entire surface of the display area DA, and may be partially disposed on the non-display area PA.

A first color conversion part CC1, a second color conversion part CC2, and a transmission part T may be disposed on the encapsulation layer ENC.

The first color conversion part CC1 overlaps the first pixel PA1, the second color conversion part CC2 overlaps the second pixel PA2, and the transmission part T overlaps the third pixel PA3.

Light emitted from the first pixel PA1 may pass through the first color conversion part CC1 to provide red light LR.

Light emitted from the second pixel PA2 may pass through the second color conversion part CC2 to provide green light LG.

Light emitted from the third pixel PA3 may pass through the transmission part T to provide blue light LB.

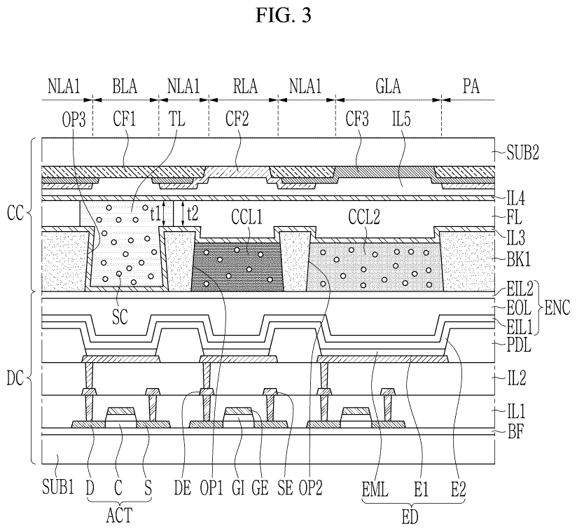

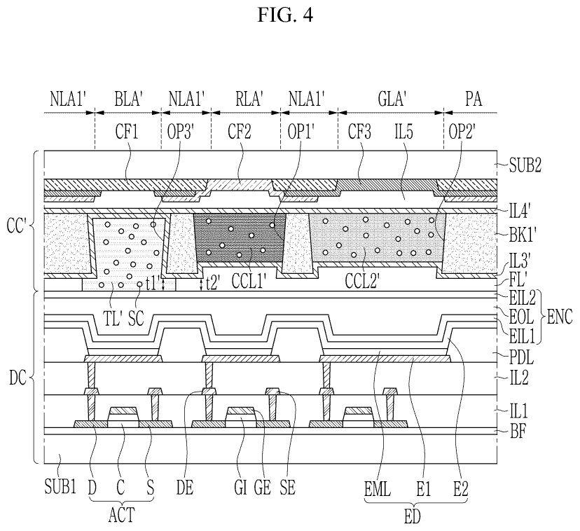

Hereinafter, the structure of the display panel according to an embodiment will be looked at in more detail with reference to FIGS. 3 and 4.

FIG. 3 and FIG. 4 are schematic cross-sectional views of a display panel according to an embodiment.

First, referring to FIG. 3, the display area DA according to an embodiment includes a red light emission area RLA, a green light emission area GLA, and a blue light emission area BLA.

A non-emission area NLA1 may be disposed between the red light emission area RLA, the green light emission area GLA, and the blue light emission area BLA.

Each light emitting area may correspond to a pixel.

For example, the blue light emitting area BLA, red light emitting area RLA, and green light emitting area GLA may correspond to blue pixels, red pixels, and green pixels, respectively.

Below, we will look at the cross-sectional structure of the display area DA.

The display part DC according to an embodiment includes a first substrate SUB1.

The first substrate SUB1 may include a flexible material such as plastic that may bend, fold, or roll.

The buffer layer BF may be disposed on the first substrate SUB1.

The buffer layer BF may include silicon nitride (SiNₓ), silicon dioxide (SiO₂), silicon oxynitride (SiOₓN_{y}), or a combination thereof.

The buffer layer BF may be disposed between the first substrate SUB1 and the semiconductor layer ACT, and improves the properties of polycrystalline silicon by blocking impurities from the first substrate SUB1 during the crystallization process to form polycrystalline silicon, and by flattening the first substrate SUB1, the stress of the semiconductor layer ACT formed on the buffer layer BF may be alleviated.

A semiconductor layer ACT may be disposed on the buffer layer BF.

The semiconductor layer ACT may be made of polycrystalline silicon or an oxide semiconductor.

The semiconductor layer ACT may include a channel region C, a source region S, and a drain region D.

The source region S and drain region D may be respectively arranged on both sides of the channel region C.

The channel region C may be an intrinsic semiconductor that may not be doped with impurities, and the source region S and drain region D may be impurity semiconductors that may be doped with conductive impurities.

The semiconductor layer ACT may be made of an oxide semiconductor. A protective layer (not shown) may be added to protect the oxide semiconductor material, which may be vulnerable to external environments such as high temperature.

A gate insulating layer GI may be disposed on the semiconductor layer ACT.

The gate insulating layer GI may be a single layer or a multilayer containing at least one of silicon nitride (SiNₓ), silicon dioxide (SiO₂), and silicon oxynitride (SiOₓN_{y}).

A gate electrode GE may be disposed on the gate insulating layer GI, the gate electrode GE includes any one of copper (Cu), a copper alloy, aluminum (Al), an aluminum alloy, molybdenum (Mo), and a molybdenum alloy, and it may be a multilayer in which metal films may be stacked on each other.

An interlayer insulating layer IL1 may be disposed on the gate electrode GE and the gate insulating layer GI.

The interlayer insulating layer IL1 may include silicon nitride (SiNₓ), silicon oxide (SiO₂), or silicon oxynitride (SiOₓN_{y}).

Openings exposing the source region S and drain region D may be disposed in the interlayer insulating layer IL1.

A source electrode SE and a drain electrode DE may be disposed on the interlayer insulating layer IL1.

The source electrode SE and drain electrode DE may be respectively electrically connected to the source region S and drain region D of the semiconductor layer ACT through an opening formed in the interlayer insulating layer IL1.

A protective film IL2 may be disposed on the interlayer insulating layer IL1, the source electrode SE, and the drain electrode DE.

The protective film IL2 covers and flattens the interlayer insulating layer IL1, the source electrode SE, and the drain electrode DE, so that the first electrode E1 may be formed on the protective film IL2 without steps.

This protective film IL2 may be made of an organic material such as polyacrylate resin or polyimide resin, or a laminated film of an organic material and an inorganic material.

The first electrode E1 may be disposed on the protective film IL2.

The first electrode E1 may be electrically connected to the drain electrode DE through an opening in the protective film IL2.

A driving transistor consisting of a gate electrode GE, a semiconductor layer ACT, a source electrode SE, and a drain electrode DE may be electrically connected to the first electrode E1 to supply a driving current to the light emitting element ED.

In addition to the driving transistor shown in FIGS. 3 and 4, the display device according to the embodiment includes a switching transistor (not shown) electrically connected to the data line and transmitting a data voltage in response to the scan signal, and a switching transistor (not shown) electrically connected to the driving transistor and transmitting a data voltage in response to the scan signal. It may further include a compensation transistor (not shown) that compensates the threshold voltage of the driving transistor in response.

A pixel defining layer PDL may be positioned on the protective layer IL2 and the first electrode E1, and the pixel defining layer PDL may have a pixel opening that overlaps the first electrode E1 and defines a light emitting area.

The pixel defining layer PDL may contain an organic material such as polyacrylate resin or polyimide resin, or a silica-based inorganic material.

The pixel opening may have a planar shape substantially similar to that of the first electrode E1, and may have a diamond or octagonal shape similar to a diamond in a plan view, but is not limited thereto and may have any shape such as a square or polygon.

The light emitting layer EML may be disposed on the first electrode E1 overlapping the pixel opening.

The light emitting layer EML may be made of a low-molecular organic material or a high-molecular organic material such as PEDOT poly(3,4-ethylenedioxythiophene).

The light emitting layer EML includes a hole injection layer HIL, a hole transporting layer HTL, an electron transporting layer ETL, and an electron injection layer EIL, and it may be a multilayer containing one or more layers.

The emitting layer EML may be disposed mostly in the pixel opening, and may also be disposed on the side or on the pixel defining layer PDL.

The second electrode E2 may be disposed on the light emitting layer EML.

The second electrode E2 may be disposed across multiple pixels and may receive a common voltage through a common voltage transmitter (not shown) in the non-display area.

The first electrode E1, the light emitting layer EML, and the second electrode E2 may form a light emitting element ED.

Here, the first electrode E1 may be an anode, which may be a hole injection electrode, and the second electrode E2 may be a cathode, which may be an electron injection electrode.

However, the embodiment is not necessarily limited to this, and the first electrode E1 may be a cathode and the second electrode E2 may be an anode depending on the driving method of the organic light emitting display device.

Holes and electrons may be injected into the light emitting layer EML from the first electrode E1 and the second electrode E2, respectively, and light emission occurs in case that the exciton that is a combination of the injected holes and electrons falls from the excited state to the ground state.

An encapsulation layer ENC may be positioned on the second electrode E2.

The encapsulation layer ENC may seal the display layer by covering not only the top surface but also the side surfaces of the display layer including the light emitting element ED.

Since the light emitting element may be very vulnerable to moisture and oxygen, the encapsulation layer ENC may seal the display layer and may block the inflow of external moisture and oxygen.

The encapsulation layer ENC may include multiple layers, and may be formed as a composite layer including both an inorganic layer and an organic layer, while including a first inorganic layer EIL1, an organic layer EOL, and a second inorganic layer, the film EIL2 may be formed of sequentially formed triple layers.

The color conversion part CC may be disposed on the encapsulation layer ENC.

The color conversion part CC includes a second substrate SUB2 that overlaps the first substrate SUB1.

The second substrate SUB2 may include a flexible material such as plastic that may bend, fold, or roll readily.

The color conversion part CC may include a bank BK1 disposed on the encapsulation layer ENC.

The bank BK1 may include a first opening OP1, a second opening OP2, and a third opening OP3 that overlap the pixel opening.

The sizes of the first opening OP1, the second opening OP2, and the third opening OP3 may be different or the same.

The first color conversion layer CCL1 may be disposed in the first opening OP1.

The first color conversion layer CCL1 may convert supplied light into red light.

The first color conversion layer CCL1 may include quantum dots.

The second color conversion layer CCL2 may be disposed in the second opening OP2.

The second color conversion layer CCL2 may convert supplied light into green light.

The second color conversion layer CCL2 may include quantum dots.

The height of the first color conversion layer CCL1 and the second color conversion layer CCL2 formed through an inkjet process may be smaller than the height of the bank BK1.

The upper surfaces of the first color conversion layer CCL1 and the second color conversion layer CCL2 may be disposed at a lower level than the upper surface of the bank BK1.

The first color conversion layer CCL1 and the second color conversion layer CCL2 may be disposed in the openings (OP1 and OP2) of the bank BK1.

Now, quantum dots will be described in detail below.

In this specification, quantum dots (hereinafter also referred to as semiconductor nanocrystals) may include group II-VI compounds, group III-V compounds, group IV-VI compounds, group IV elements or compounds, group I-III-VI compounds, and group II-III compounds. It may include a group-VI compound, a group I-II-IV-VI compound, or a combination thereof.

The II-VI group compounds may include binary compounds selected from the group consisting of CdSe, CdTe, ZnS, ZnSe, ZnTe, ZnO, HgS, HgSe, HgTe, MgSc, MgS, and mixtures thereof; AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; a group consisting of a tri-element compound selected from; and a tetraelement compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The group II-VI compound may further include a Group III metal.

The group III-V group compounds may include binary compounds selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof.

The group III-V compound may further include a group II metal (e.g., InZnP).

The IV-VI group compounds may include binary compounds selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary element compound selected from the group consisting of SnPbSSe, SnPbSeTe, SnPbSTe, and mixtures thereof.

The Group IV element or compound may be a single-element material selected from the group consisting of Si, Ge, and combinations thereof; or a binary compound selected from the group consisting of SiC, SiGe, and combinations thereof, but is not limited thereto.

Examples of the group I-III-VI compounds may include, but are not limited to, CuInSe2, CuInS2, CuInGaSe, and CuInGaS.

Examples of the group I-II-IV-VI compounds may include, but are not limited to, CuZnSnSe and CuZnSnS.

The group IV element or compound may be a single element selected from the group consisting of Si, Ge, and mixtures thereof; or a binary compound selected from the group consisting of SiC, SiGe, and mixtures thereof.

The group II-III-VI compounds may include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, or may be selected from the group consisting of HgInTe, MgGaS, MgAlS, MgInS, MgGaSe, MgAlSe, MgInSe, and combinations thereof, but are not limited thereto.

The group I-II-IV-VI compound may be selected from CuZnSnSe and CuZnSnS, but is not limited thereto.

In an embodiment, the quantum dots may not include cadmium.

Quantum dots may include semiconductor nanocrystals based on group III-V compounds including indium and phosphorus.

The group III-V compound may further include zinc.

Quantum dots may include semiconductor nanocrystals based on II-VI compounds including chalcogen elements (e.g., sulfur, selenium, tellurium, or combinations thereof) and zinc.

In quantum dots, the above-mentioned di-element compound, tri-element compound, and/or quaternary compound may exist in the particle at a uniform concentration, or may exist in the same particle with a concentration distribution partially divided into different states.

A quantum dot may have a core/shell structure surrounding other quantum dots.

The interface between the core and the shell may have a concentration gradient in which the concentration of elements in the shell decreases toward the center.

In some embodiments, quantum dots may have a core-shell structure including a core containing the above-described nanocrystals and a shell surrounding the core.

The shell of the quantum dot may serve as a protective layer to maintain semiconductor properties by preventing chemical denaturation of the core and/or as a charging layer to impart electrophoretic properties to the quantum dot.

The shell may be single or multi-layered.

The interface between the core and the shell may have a concentration gradient in which the concentration of elements in the shell decreases toward the center.

Examples of the shell of the quantum dot may include metal or non-metal oxides, semiconductor compounds, or combinations thereof.

For example, the oxide of the metal or non-metal may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, CoMn₂O₄, etc., or a combination thereof, but the disclosure is not limited thereto.

The semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., or a combination thereof. However, the disclosure is not limited thereto.

The interface between the core and the shell may have a concentration gradient in which the concentration of elements in the shell decreases toward the center.

The semiconductor nanocrystal may have a structure including a single semiconductor nanocrystal core and a multi-layered shell surrounding it.

In an embodiment, the multilayer shell may have two or more layers, such as 2, 3, 4, 5, or more layers.

The two adjacent layers of the shell may have a single composition or different compositions.

In a multilayer shell, each layer may have a composition that changes along the radius.

Quantum dots may have a full width at half maximum (FWHM) of the emission wavelength spectrum of about 45 nm or less, preferably about 40 nm or less, more preferably about 30 nm or less, and in these range, color purity or color reproducibility may be improved.

Since the light emitted through these quantum dots may be emitted in all directions, the optical viewing angle may be improved.

The quantum dots may have different energy band gaps between the shell material and the core material.

For example, the energy band gap of the shell material may be larger than that of the core material.

In other embodiments, the energy band gap of the shell material may be smaller than that of the core material.

The quantum dots may have a multi-layered shell.

In a multilayer shell, the energy band gap of the outer layer may be larger than that of the inner layer (i.e., the layer close to the core).

In a multilayer shell, the energy band gap of the outer layer may be smaller than that of the inner layer.

Quantum dots may control absorption/emission wavelengths by adjusting their composition and size.

The maximum emission peak wavelength of the quantum dot may range from ultraviolet to infrared wavelengths or longer.

Quantum dots may have a quantum efficiency of at least about 10%, such as at least about 30%, at least about 50%, at least about 60%, at least about 70%, at least about 90%, or even at least 100%.

Quantum dots may have a relatively narrow spectrum.

The quantum dots may have a full width at half maximum of the emission wavelength spectrum of, for example, about 50 nm or less, such as about 45 nm or less, about 40 nm or less, or about 30 nm or less.

The quantum dots may have a particle size of about 1 nm or more and about 100 nm or less.

The size of a particle refers to the diameter of the particle or the diameter converted by assuming a spherical shape from a two-dimensional image obtained by transmission electron microscope analysis.

The diameter of the quantum dots may be about 1 nm to about 20 nm, such as at least about 2 nm, at least about 3 nm, or at least about 4 nm and at most about 50 nm, at most about 40 nm, at most about 30 nm, at most about 20 nm, or at most about 15 nm, such as at least about 10 nm

The shape of the quantum dot may be not particularly limited.

For example, the shape of the quantum dot may include, but is not limited to, a sphere, polyhedron, pyramid, multipod, square, cuboid, nanotube, nanorod, nanowire, nanosheet, or a combination thereof.

Quantum dots may be commercially available or may be appropriately synthesized.

The particle size of quantum dots may be controlled relatively freely during colloid synthesis, and the particle size may also be adjusted uniformly.

Quantum dots may include organic ligands (e.g., having hydrophobic and/or hydrophilic moieties).

The organic ligand residue may be bound to the surface of the quantum dot.

The organic ligand includes RCOOH, RNH₂, R₂NH, R₃N, RSH, R₃PO, R₃P, ROH, RCOOR, RPO(OH)₂, RHPOOH, R₂POOH, or a combination thereof, where R may be each independently a C3 to substituted or unsubstituted alkyl of C₄0 (e.g., C5 or more and C24 or less), substituted or unsubstituted alkenyl, a substituted or unsubstituted aliphatic hydrocarbon group of C3 to C40, a substituted or unsubstituted aryl group of C6 to C40, or may be a substituted or unsubstituted aromatic hydrocarbon group of C6 to C40 (e.g., C6 or more and C20 or less), or a combination thereof.

Examples of the organic ligand include at least one of thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, and amines such as tributylamine, trioctylamine, etc.; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, trioctyl phosphine, etc.; phosphines such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide; compounds or its oxide compounds; diphenyl phosphine, and triphenyl phosphine compounds or their oxide compounds; C5 to C20 alkyl phosphinic acids, C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid; and examples include, but are not limited to these.

Quantum dots may include hydrophobic organic ligands alone or in a mixture of one or more types.

The hydrophobic organic ligand may not contain a photopolymerizable residue (e.g., an acrylate group, a methacrylate group, etc.).

The first insulating layer IL3 may be disposed on the bank BK1, the first color conversion layer CCL1, and the second color conversion layer CCL2.

The first insulating layer IL3 may have a shape that covers the bank BK1, the first color conversion layer CCL1, and the second color conversion layer CCL2.

The first insulating layer IL3 may include at least one of silicon nitride, silicon oxide, and silicon oxynitride.

According to an embodiment, the first insulating layer IL3 may be omitted.

According to an embodiment, the transmission layer TL may be disposed in the third opening OP3 of the bank BK1.

A transmission layer TL may be disposed in a portion corresponding to the blue light emission area BLA in the space partitioned by the bank BK1.

The transmission layer TL may include a scatterer SC.

The scatterer SC may be one or more selected from the group consisting of SiO₂, BaSO₄, Al₂O₃, ZnO, ZrO₂, and TiO₂.

The transmission layer TL may include a polymer resin and scatterers included in the polymer resin.

For example, the transmission layer TL may include TiO₂, but is not limited thereto.

The transmission layer TL may transmit light incident from the light emitting element ED.

The height of the transmission layer TL may be greater than the height of the bank BK1.

The height of each of the first color conversion layer CCL1 and the second color conversion layer CCL2 may be smaller than the height of the bank BK1.

The gap between components may be maintained during the bonding process of the second substrate SUB2 and the first substrate SUB1 by the transmission layer TL having a relatively high height.

The transmission layer TL may function as a column spacer.

The upper surface of the transmission layer TL may have an approximately flat surface.

At least a portion of the transmission layer TL may be disposed on the upper part of the bank BK1.

The transmission layer TL may have a shape that fills the third opening OP3 and even covers a portion of the upper surface of the bank BK1.

In the display panel according to this embodiment, the first color conversion layer CCL1 converts the incident light into red light and emits the red light.

The second color conversion layer CCL2 converts the incident light into green light and emits the green light.

However, the light incident on the transmission layer TL may be transmitted without color conversion.

The incident light may include blue light.

The incident light may be blue light alone or a mixture of blue light and green light.

The incident light may include all of blue light, green light, and red light.

The filling layer FL may be disposed on the first insulating layer IL3.

The filling layer FL may be disposed on the bank BK1, the first color conversion layer CCL1, and the second color conversion layer CCL2.

The filling layer FL may combine components disposed on the first substrate SUB1 and components disposed on the second substrate SUB2.

A display panel may be formed through the filling layer FL.

According to an embodiment, the top surface of the filling layer FL and the top surface of the transmission layer TL may be disposed at substantially a same level.

The top surface of the filling layer FL and the top surface of the transmission layer TL may be disposed on a same surface.

The first thickness t1 of the transmission layer TL disposed on the upper surface of the bank BK1 may be substantially equal to the second thickness t2 of the filling layer FL disposed on the upper surface of the bank BK1.

The transmission layer TL may function as a column spacer to maintain the gap.

A second insulating layer IL4 may be disposed on the transmission layer TL and the filling layer FL.

The second insulating layer IL4 may include, for example, silicon nitride (SiNₓ), silicon dioxide (SiO₂), silicon oxynitride SiOₓN_{y}, or a combination thereof.

Depending on the embodiment, the second insulating layer IL4 may be omitted.

A third insulating layer IL5 may be disposed on the second insulating layer IL4.

For example, the third insulating layer IL5 may include an organic material or an inorganic material such as silicon nitride (SiNₓ), silicon dioxide (SiO₂), silicon oxynitride (SiOₓN_{y}), or a combination thereof.

The color conversion part CC may include a first color filter CF1, a second color filter CF2, and a third color filter CF3 disposed between the second substrate SUB2 and the display part DC.

The first color filter CF1 may overlap the transmission layer TL.

The first color filter CF1 may transmit blue light that has passed through the transmission layer TL and absorb light of the remaining wavelengths, thereby increasing the purity of blue light emitted to the outside of the display device.

The second color filter CF2 may overlap the first color conversion layer CCL1.

The second color filter CF2 may transmit red light that has passed through the first color conversion layer CCL1 and absorb light of the remaining wavelengths, thereby increasing the purity of red light emitted to the outside of the display device.

The third color filter CF3 may overlap the second color conversion layer CCL2.

The third color filter CF3 may transmit green light that has passed through the second color conversion layer CCL2 and absorb light of the remaining wavelengths, thereby increasing the purity of green light emitted to the outside of the display device.

At least two of the third color filter CF3, the second color filter CF2, and the first color filter CF1 may overlap in the non-emission area NLA1 and serve as a light blocking member.

The non-emission area NLA1 may overlap the pixel defining layer PDL of the display part DC and the bank BK1 of the color conversion part CC.

In the non-display area PA and disposed on the first substrate SUB1, there may be a buffer layer BF extended from the display area DA, an interlayer insulating layer IL1, a passivation layer IL2, a second electrode E2, an encapsulation layer ENC, a bank BK1, a first insulating layer IL3, a filling layer FL, a second insulating layer IL4, and a third insulating layer IL5.

At least one of these may be omitted.

Moreover, the first color filter CF1, the second color filter CF2, and the third color filter CF3 may be continuously overlapped between the second substrate SUB2 and the display part DC to overlap an entire surface of the non-display area PA.

The first color filter CF1, the second color filter CF2, and the third color filter CF3 may serve as a light blocking member to prevent the non-display area PA from being visible.

A portion of the bank BK1 may be disposed in the non-display area PA.

A filling layer FL may be disposed in the non-display area PA, and a column spacer may not be disposed in the non-display area PA.

According to an embodiment, the transmission layer TL functions as a column spacer, and a separate column spacer may not be required.

Therefore, it may be possible to omit the area where the column spacer may be disposed, and a high-resolution display device may be provided.

In addition, according to an embodiment, even if foreign material may be disposed on the encapsulation layer ENC, dents due to bonding of the first substrate SUB1 and the second substrate SUB2 may be prevented, so the reliability of the device may be improved.

Hereinafter, a display panel according to an embodiment will be described with reference to FIG. 4.

Descriptions of components that may be the same as those described in FIG. 3 will be omitted.

The structure of the display part DC according to an embodiment may be the same as the stacked structure of the display part DC described in FIG. 3.

The color conversion part CC′ may be disposed on the encapsulation layer ENC.

The color conversion part CC′ may include a second substrate SUB2 that overlaps the first substrate SUB1.

The second substrate SUB2 may include a flexible material such as plastic that may bend, fold, or roll readily.

The color conversion part CC′ may include a first color filter CF1, a second color filter CF2, and a third color filter CF3 disposed between the second substrate SUB2 and the display part DC.

The first color filter CF1 may overlap the transmission layer TL′.

The first color filter CF1 may transmit blue light that has passed through the transmission layer TL and absorb light of the remaining wavelengths, thereby increasing the purity of blue light emitted to the outside of the display device.

The second color filter CF2 may overlap the first color conversion part CCL1′.

The second color filter CF2 may transmit red light that has passed through the first color conversion layer CCL1′ and absorb light of the remaining wavelengths, thereby increasing the purity of red light emitted to the outside of the display device.

The third color filter CF3 may overlap the second color conversion layer CCL2′.

The third color filter CF3 may transmit green light that has passed through the second color conversion layer CCL2′ and absorb light of the remaining wavelengths, thereby increasing the purity of green light emitted to the outside of the display device.

At least two of the third color filter CF3, the second color filter CF2, and the first color filter CF1 may overlap in the non-emission area NLA1 and serve as a light blocking member.

The non-emission area NLA1 may overlap the pixel defining layer PDL of the display part DC and the bank BK1′ of the color conversion part CC.

The color conversion part CC may include a low refractive index layer IL5 and a protective layer IL4′ disposed between the color filters (CF1, CF2, and CF3) and the display part DC.

According to an embodiment, each of the low refractive index layer IL5 and the protective layer IL4′ may include an organic insulating material or an inorganic insulating material.

Depending on the embodiment, at least one of the low refractive index layer IL5 and the protective layer IL4′ may be omitted.

A bank BK1′ may be disposed between the protective layer IL4′ and the display part DC.

The bank BK1′ may include a first opening OP1′, a second opening OP2′, and a third opening OP3′ that overlap the pixel opening.

The sizes of the first opening OP1′, the second opening OP2′, and the third opening OP3′ may be different or the same.

The first color conversion layer CCL1′ may be disposed in the first opening OP1′.

The first color conversion layer CCL1′ may convert supplied light into red.

The first color conversion layer CCL1′ may include quantum dots.

The second color conversion layer CCL2′ may be disposed in the second opening OP2′.

The second color conversion layer CCL2′ may convert supplied light into green.

The second color conversion layer CCL2′ may include quantum dots.

The height of the first color conversion layer CCL1′ and the second color conversion layer CCL2′ formed through an inkjet process may be smaller than the height of the bank BK1′.

The first color conversion layer CCL1′ and the second color conversion layer CCL2′ may be disposed in the first opening OP1 and the second opening OP2 respectively of the bank BK1′.

An insulating layer IL3′ may be positioned between the display part DC and each of the bank BK1′, the first color conversion layer CCL1′, and the second color conversion layer CCL2′.

The insulating layer IL3′ may have a shape that covers the bank BK1′, the first color conversion layer CCL1′ and the second color conversion layer CCL2′.

The insulating layer IL3′ may include at least one of a silicon nitride, a silicon oxide, and a silicon oxynitride.

According to an embodiment, the insulating layer IL3′ may be omitted.

According to an embodiment, the transmission layer TL′ may be disposed in the third opening OP3′ of the bank BK1′.

The transmission layer TL′ may be disposed in a portion corresponding to the blue light emission area BLA in the space barrier partitioned by the bank BK1′.

The transmission layer TL′ may include a scatterer SC.

The scatterer SC may be one or more selected from the group consisting of SiO₂, BaSO₄, Al₂O₃, ZnO, ZrO₂, and TiO₂.

The transmission layer TL′ may include a polymer resin and scatterers included in the polymer resin.

For example, the transmission layer TL′ may include TiO₂, but is not limited thereto.

The transmission layer TL′ may transmit light incident from the light emitting element ED.

The height of the transmission layer TL′ may be greater than the height of the bank BK1′.

The height of the first color conversion layer CCL1′ and the second color conversion layer CCL2′ may be smaller than the height of the bank BK1′.

The gap between components may be maintained during the bonding process of the second substrate SUB2 and the first substrate SUB1 by the transmission layer TL′ having a relatively high height.

The transmission layer TL′ may function as a column spacer.

The upper surface of the transmission layer TL′ may have an approximately flat surface.

At least a portion of the transmission layer TL′ may be disposed on a side of the bank BK1′.

The transmission layer TL′ may have a shape that fills the third opening OP3′ and even covers a portion of the upper surface of the bank BK1′.

In the display panel according to this embodiment, the first color conversion layer CCL1′ converts the incident light into red light and emits the red light.

The second color conversion layer CCL2′ converts the incident light into green light and emits the green light.

However, the light incident on the transmission layer TL′ may be transmitted without color conversion.

The incident light may include blue light.

The incident light may be blue light alone or a mixture of blue light and green light.

It may include all of blue light, green light, and red light.

A filling layer FL′ may be disposed between the insulating layer IL3′ and the display part DC.

The filling layer FL′ may be disposed on the bank BK1′, the first color conversion layer CCL1′, and the second color conversion layer CCL2′.

The filling layer FL′ may combine components disposed on the first substrate SUB1 and components disposed on the second substrate SUB2.

A display panel may be formed through the filling layer FL′.

According to an embodiment, a surface of the filling layer FL′ and a surface of the transmission layer TL′ may be disposed at substantially the same level.

The surface of the filling layer FL′ and the surface of the transmission layer TL′ may be disposed on the same plane.

The first thickness t1′ of the transmission layer TL′ disposed on the upper surface of the bank BK1′ may be substantially equal to the second thickness t2′ of the filling layer FL′ disposed on the upper surface of the bank BK1′.

The transmission layer TL′ may function as a column spacer to maintain the gap.

According to FIG. 4, the transmission layer TL′ may contact the display part DC, and in particular, may contact the encapsulation layer ENC.

However, it is not limited to this structure, and the components in contact with the transmission layer TL′ may vary depending on the stacked structure of the display part DC.

The transmission layer TL′ and the filling layer FL′ may be in contact with the same component.

A portion of the bank BK1′ may be disposed in the non-display area PA.

A filling layer FL′ may be disposed in the non-display area PA, and a column spacer may not be disposed in the non-display area PA.

According to an embodiment, the transmission layer TL′ functions as a column spacer, and a column spacer may not be required.

Therefore, it may be possible to omit the area where the column spacer may be disposed, and a high-resolution display device may be provided.

Although the embodiments of the disclosure have been described in detail above, the scope of the disclosure is not limited thereto, and various modifications and improvements may be made by those skilled in the art using the basic concepts of the disclosure defined in the following claims.

What is claimed is:

1. A display device, comprising:
a first substrate;
a transistor disposed on the first substrate;
a light emitting element electrically connected to the transistor;
an encapsulation layer disposed on the light emitting element;
a bank disposed on the encapsulation layer and including a first opening, a second opening, and a third opening;
a first color conversion layer disposed in the first opening;
a transmission layer disposed in the third opening; and
a filling layer disposed on the first color conversion layer and the bank, wherein
a height of the transmission layer is greater than a height of the bank, and
a surface of the filling layer and a surface of the transmission layer are disposed on a same surface.

2. The display device of claim 1, further comprising:
a second color conversion layer disposed in the second opening.

3. The display device of claim 2, wherein the height of the bank is larger than each of a height of the first color conversion layer and a height of the second color conversion layer.

4. The display device of claim 1, further comprising:
a second substrate overlapping the first substrate; and
a color filter disposed on a surface of the second substrate.

5. The display device of claim 4, wherein the filling layer is disposed between the color filter and the first color conversion layer.

6. The display device of claim 1, wherein at least a portion of the transmission layer is disposed on an upper surface of the bank.

7. The display device of claim 6, wherein a first thickness of the transmission layer is equal to a second thickness of the filling layer disposed on a surface of the bank.

8. The display device of claim 1, wherein
the first substrate includes a non-display area,
the display device further comprises a first color filter, a second color filter, and a third color filter, and
at least two of the first color filter, the second color filter and the third color filter overlap each other in the non-display area.

9. The display device of claim 8, wherein the bank and the filling layer are disposed in the non-display area.

10. A display device, comprising:
a first substrate;
a transistor disposed on the first substrate;
a light emitting element electrically connected to the transistor;
an encapsulation layer disposed on the light emitting element;
a second substrate overlapping the first substrate;
a bank disposed between the first substrate and the second substrate and including an opening; and
a color conversion layer and a transmission layer respectively disposed in the opening,
wherein a height of the transmission layer is greater than a height of the bank.

11. The display device of claim 10, wherein
the opening in the bank includes a first opening, a second opening, and a third opening, and
the color conversion layer comprises:
a first color conversion layer disposed in the first opening;
a second color conversion layer disposed in the second opening; and
the transmission layer disposed in the third opening.

12. The display device of claim 11, wherein the height of the bank is larger than each of a height of the first color conversion layer and a height of the second color conversion layer.

13. The display device of claim 11, further comprising:
a color filter disposed between the second substrate and the color conversion layer.

14. The display device of claim 13, further comprising:
a filling layer disposed between the color conversion layer and the encapsulation layer.

15. The display device of claim 14, wherein a surface of the filling layer and a surface of the transmission layer are disposed on a same surface.

16. The display device of claim 14, wherein a first thickness of the transmission layer is equal to a second thickness of the filling layer disposed on a surface of the bank.

17. The display device of claim 10, wherein the transmission layer is in contact with the encapsulation layer.

18. The display device of claim 14, wherein
the first substrate includes a non-display area,
the display device further comprises a first color filter, a second color filter, and a third color filter, and
at least two of the first color filter, the second color filter and the third color filter overlap each other in the non-display area.

19. The display device of claim 18, wherein the bank and the filling layer are disposed in the non-display area.

20. The display device of claim 10, wherein at least a portion of the transmission layer is disposed on a surface of the bank.
